(19) United States
(12) Patent Application Publication
(10) Pub. No.: US 2014/0113526 A1
(43) Pub. Date: Apr. 24, 2014

(54) WAFER PROCESS CONTROL

(71) Applicants: Ran Kipper, Mazkeret Batya (IL); Tommy Weiss, Sunnyvale, CA (US)

(72) Inventors: Ran Kipper, Mazkeret Batya (IL); Tommy Weiss, Sunnyvale, CA (US)

(21) Appl. No.: 14/054,861

(22) Filed: Oct. 16, 2013

Related U.S. Application Data
(60) Provisional application No. 61/716,548, filed on Oct. 21, 2012.

(51) Int. Cl. B24B 37/013; H01L 21/304; B24B 49/12

(52) U.S. Cl. CPC B24B 37/013; B24B 49/12; H01L 21/304
USPC 451/5; 451/6

(57) ABSTRACT

A system for controlling a manufacturing process of a substrate, the system may include an illumination module that is arranged to illuminate multiple regions of a substrate with electromagnetic radiation; a detection module that is arranged to detect electromagnetic signals resulting from the illumination of the multiple regions; and a processor that is arranged to: determine dimensions of multiple vias that are deposited within a substrate of the substrate to provide first via measurement results; determine substrate thickness at multiple locations to provide first substrate thickness results; and provide information related to at least one out of (a) the first substrate thickness results and (b) the first via measurement results to at least one out of (i) a thinning device arranged to thin the substrate and (ii) a manufacturing device that differs from the thinning device and is arranged to participate in a manufacturing of the substrate.

### RELATED APPLICATIONS

This application claims priority from U.S. provisional patent Ser. No. 61/716,548 filing date Oct. 21, 2012, which is incorporated herein by reference.

### BACKGROUND

The need to control the backside grinding of a Silicon wafer is a critical step in achieving cost effective, production worthy three dimensional (3DiC) packaging process. More specific, it is the key in enabling cost-effective Through Silicon Via (TSV) process which is one of the foundation of the 3DiC revolution.

The need is for removal of the Silicon bulk from the backside of the wafer using typical backside grinding devices (e.g. Disco 8000 series). During a grinding process, the grinding device task is to remove more than 600 μm from the backside of the silicon wafer (of the Silicon bulk) with minimum damage to the wafer and stop at the predefined point with micron accuracy. After the removal of the Silicon bulk material, the TSVs are still buried under a much thinner Silicon layer. The wafer is then moved to the next step where the TSV edges are exposed.

The wafer backside grinding may be done in a two-phase grinding process. The first phase is a fast (coarse) grinding phase that employs a coarse grinding wheel with larger diamond abrasives the remove majority of the total removal amount required. The subsequent fine grinding phase uses a slower feed-rate and a fine grinding wheel with smaller diamond abrasives. The fine grinding phase of the gringing process is necessary to remove most of the damage layer created by the coarse grinding phase (such as grinding marks and subsurface cracks) and reduce surface roughness. The coarse grinding phase cracks could penetrate up to 10 μm deep into the wafer, depends on diamond grain size of the grinding device wheel. Consequently, this is the thickness range that is expected for the fine grinding phase. It is important to note that this two-steps grinding process has no indication on the presence of the TSVs deep inside the Silicon bulk and their edges proximity to the silicon edge. The challenge is to stop very close to the bottom of TSVs, metalized (or filled or loaded) or not, without damaging the wafer or TSVs. The typical requirement for the grinding process is to leave a layer of 1 μm to 10 μm of remaining silicon from the bottom of the TSV. In order to leave such a thin layer of remaining silicon across the whole wafer, the process has to be tightly and effectively controlled (for example, in order to allow “real-time” change of the grinding time or rates to compensate for variations in the process).

### SUMMARY

There may be provided according to an embodiment of the invention a system for controlling a manufacturing process of a substrate, the system may include an illumination module that is arranged to illuminate multiple regions of a substrate with electromagnetic radiation; a detection module that is arranged to detect electromagnetic signals resulting from the illumination of the multiple regions; and a processor that is arranged to: determine dimensions of multiple vias that are deposited within the substrate to provide first via measurement results; determine substrate thickness at multiple locations to provide first substrate thickness results; and provide information related to at least one out of (a) the first substrate thickness results and (b) the first via measurement results to at least one out of (i) a thinning device arranged to thin the substrate and (ii) a manufacturing device that differs from the thinning device and is arranged to participate in a manufacturing of the substrate. Different examples of various “dimensions of multiple vias” or so called “via Information” are described in par. [0055] and [0058] below.

There may be provided according to an embodiment of the invention a system for controlling a manufacturing process of a substrate, the method may include measuring dimensions of multiple through silicon vias that are deposited within the substrate to provide first via measurement results; wherein the measuring comprises illuminating the vias with electromagnetic radiation; measuring substrate thickness at multiple locations to provide a first substrate thickness results; and providing information related to at least one out of (a) the first substrate thickness results and (b) the first via measurement results to at least one out of (i) a thinning device arranged to thin the substrate and (ii) a manufacturing device that differs from the thinning device and is arranged to participate in a manufacturing of the substrate. Different examples of various “dimensions of multiple vias” or so called “via information” are described in par. [0055] and [0058] below.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates a system and a cross section of a wafer in which TSV holes are formed during one of manufacturing processes controlled according to an embodiment of the invention;

FIG. 2 illustrates a system and a cross section of wafer in which TSVs are loaded with appropriated metal thin layer that may be controlled according to an embodiment of the invention;

FIG. 3 illustrates a wafer that includes regions that include deepest and shallowest TSVs that may be controlled according to an embodiment of the invention;

FIG. 4 illustrates a chuck and a cross section of wafer that include a wafer with top layers on it, TSVs, an adhesive layer and a carrier layer that may be controlled according to an embodiment of the invention;

FIG. 5A illustrates a cross section of a wafer before attaching the carrier to an alignment tape, that may be controlled according to an embodiment of the invention;

FIG. 5B illustrates a cross section of a wafer after attaching the wafer to an alignment tape, that may be controlled according to an embodiment of the invention;

FIG. 5C illustrates a cross section of a wafer after cutting the alignment tape to provide an aligned wafer, according to an embodiment of the invention;

FIG. 6 illustrates a cross section of a wafer, and various dimensions that are associated with a fine phase and a coarse phase of a grinding process that may be controlled according to an embodiment of the invention;

FIG. 7 illustrates a cross section of a wafer after a completion of a coarse phase of a grinding process, and various dimensions that are associated with a fine phase and the coarse phase of the grinding process that may be controlled according to an embodiment of the invention;

FIG. 8 illustrates a system that measures depths of TSVs of a wafer that was coarsely grinded according to an embodiment of the invention;

FIG. 9 illustrates a cross section of a wafer after a completion of a fine phase of a grinding process, and various dimensions that are associated with the fine phase of the grinding process that may be controlled according to an embodiment of the invention;

FIG. 10 illustrates a system that measures depths of TSVs of a wafer that was coarsely and finely grinded according to an embodiment of the invention;

FIG. 11 illustrates a system that performs post etch measurements of TSVs according to an embodiment of the invention;

FIG. 12 illustrates a system that performs post etch measurements of TSVs according to an embodiment of the invention; and

FIG. 13 illustrates a method according to an embodiment of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method.

Any reference in the specification to a system should be applied mutatis mutandis to a method that may be executed by the system

Some of the following examples refer to a wafer and especially to a wafer that include one or more Silicon layers and/or a Silicon bulk. It is noted that a wafer is only a non-limiting example of a substrate and that Silicon is just one non-limiting example of materials from which a substrate can be made. Accordingly—any of the methods illustrated below can be applied mutatis mutandis to substrates that differ from wafers and to materials that differ from silicone. Furthermore—through silicon vias (TSVs) is only one example to vias of any type and are used to electrically connect the substrate to another electrical component and can be used to connect elements of the substrate to each other.

The term bulk can be interpreted as being a layer of material of a substrate that is formed at the bottom side of the substrate. The bulk can be thinned during a thinning process, whereas the term “grinding” is used only as a non-limiting example of thinning processes that a substrate may undergo (and may include polishing, grounding, backgrindning, baklapping, etc.).

According to an embodiment of the invention fine grinding phase time will be controlled to allow changes in the total thickness of the Silicon removed. It is assumed that total range of 1 μm to 10 μm will be sufficient to control the process,

The control of the feed rate and calculation of the fine grinding phase time could be done on a wafer bases or on a wafer lot bases. It will be mostly depends on source of changes in the remaining silicon on top of the TSV. If the main phenomenon that needs control is the grinding rate degradation due to the ware-out of the pads then a lot to lot compensation will be sufficient. If the contribution of the TSV silicon-etch process is on the same order of variation then a wafer based correction will be required.

The grinding time of the fine grinding phase (t_{Fg}) can be extracted from the following equation

T_{final}=T_{wafer}−(t_{Pg}×GR_{Pg}+T_{TSV}+t_{Fg}×GR_{Fg})

Where:

T_{final} is the desired remaining Silicon thickness after a completion of the fine grinding phase.

T_{wafer} is the Silicon wafer total thickness.

t_{Cg} is the total time of the coarse grinding phase.

GR_{Cg} is the material removal rate during the coarse grinding phase.

T_{TSV} is the thickness of the TSV post Silicon etch.

t_{Fg} is the total time of the fine grinding phase.

GR_{Fg} is the material removal rate during the fine grinding phase.

The above simple calculation can lead to various control schemes depending on the tolerances allowed for each parameter and the nature of the variation in each one. For example if all parameters are fixed except GR_{Gg} or GR_{Fg} that changes slowly—then the lot- to-lot (LtL) control can be adopted.

In this case the additional grinding relative to the time grinding time of the current lot is given by:

$${t}_{Fg}^{i + 1} = {t}_{Fg}^{i} + \frac{{T}_{Rs}^{i} - {T}_{final}}{{GR}_{Fg}}$$

Where

T_{Rs} is the thickness of the remaining Silicon.

Index i stands for the current lot grinding parameters.

Value i+1 represents the grinding parameter for the next lot.

Measurement Technology

Whatever control scheme will be chosen, the calculation of t_{Fg}ⁱ⁺¹ will be based on measurement of several parameters that will be used as inputs for the calculation.

The parameters may be:

T_{wafer}—is in the range of a standard prime silicon wafer ˜750 μm to ˜760 μm.

T_{TSV}—is in the range of ˜80 μm to ˜100 μm.

TSV diameter is in the range of at least 5 μm.

T_{Rs}—is the remaining Silicon thickness above the TSV edge after a completion of the grinding process, it can be in the range of 1 μm to 10 μm.

GR_{Cg} is assumed to be known with reasonable accuracy during the lifetime of the grinding pad. However, GR_{Cg} can be also measured by a combination of two measurement techniques.

There may be provided an inspection system, such as Camtek AOI product Condor which may include a two dimensional inspection module, and up to three metrology modules: (i) Spectroscopic Reflectometry Module, (ii) Chromatic Confocal Sensor and (iii) Triangulation system.

Spectroscopic Reflectometry Module (SRM)—This module is based on white light (including NIR spectral range) spectroscopic reflectometry design to measure thick film. The measurement is done using a small adaptive illumination spot in a range of few microns. The SRM may automatically find pre-defined measurement locations, as is set in the recipe, and navigates the wafer to the measurement location.

The SRM may be used to measure parameters needed for the calculation above: Depth of TSVs—(T_{TSV}) and

Remaining silicon thickness T_{RS} which is the parameter that needs to be controlled in order to reach to the desired reaming silicon thickness T_{final}.

Chromatic Confocal Sensor (CCS)—This optical module may measure the distance of a surface level relative to a given reference surface within nanometers accuracy scale. The measurement is performed using a very small optical spot that defines the measurement location. The CCS module can be also used in an “area scan” mode. In this case a small area is scanned with the small optical spot and creates detailed 3D map of the area. This mode is usually used for engineering purposes due to the slow TPT and the huge amount of data gathered from the small area. In both cases the system is automatically navigates to the measurement or scan location as set by the recipe.

The CCS can be used to measure T_{wafer}. This is done by measuring the distance of the chuck without a wafer to the reference surface and the distance in the same location with wafer mounted on the chuck. Additionally or alternatively, the CCS can be used, for example, for alignment measurements of the wafer, and post etch measurements

Triangulation System (CTS)—Triangulation is the most cost effective, production worthy method to measure bump height. In fact, it is the dominant technology for this application and widely used by all semiconductor and back-end Fabs. The CTS may be used for measuring the exposed (post etch) TSV after the Silicon etch process. The measurement can be done on the whole wafer at high accuracy and repeatability to ensure the bottom line performance of the process and validate the readiness of the wafer to move to the next step.

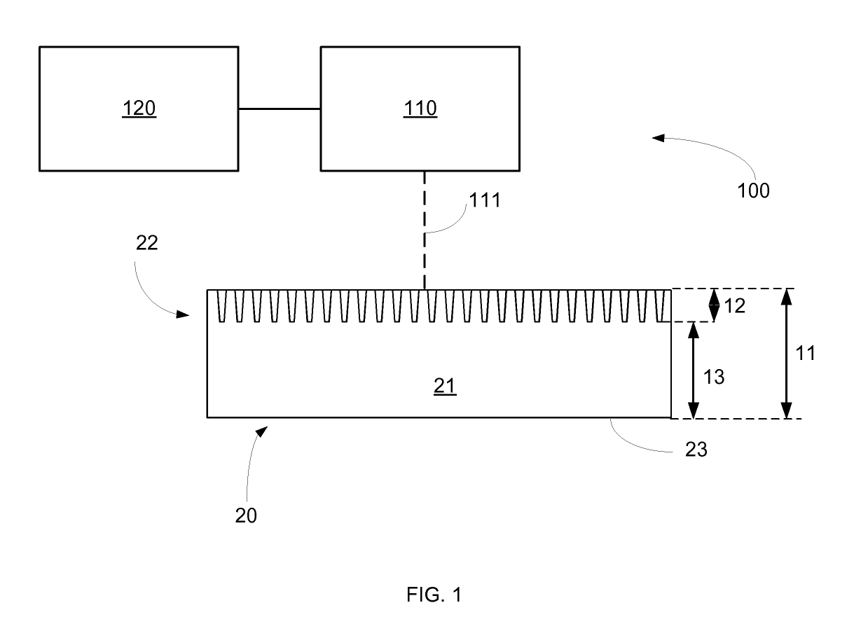

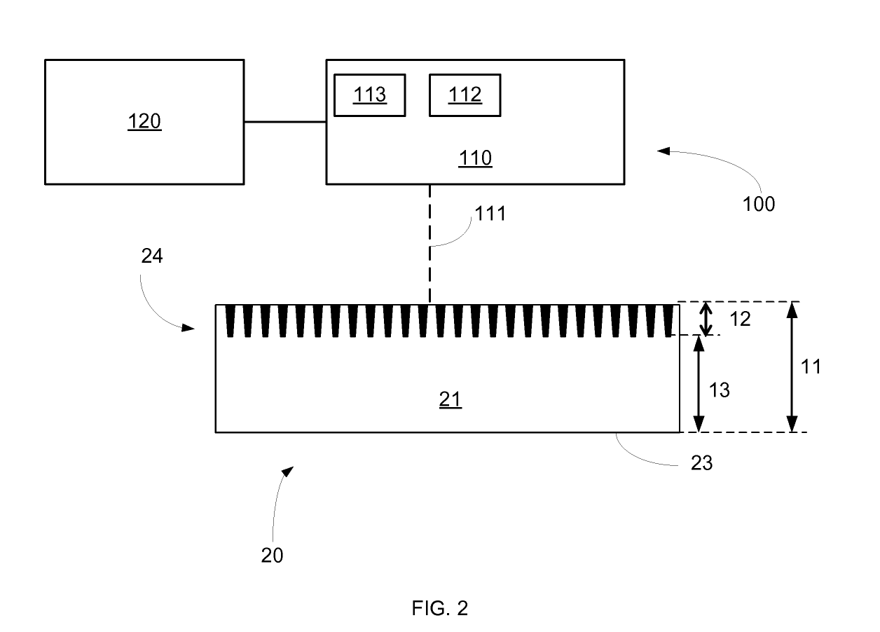

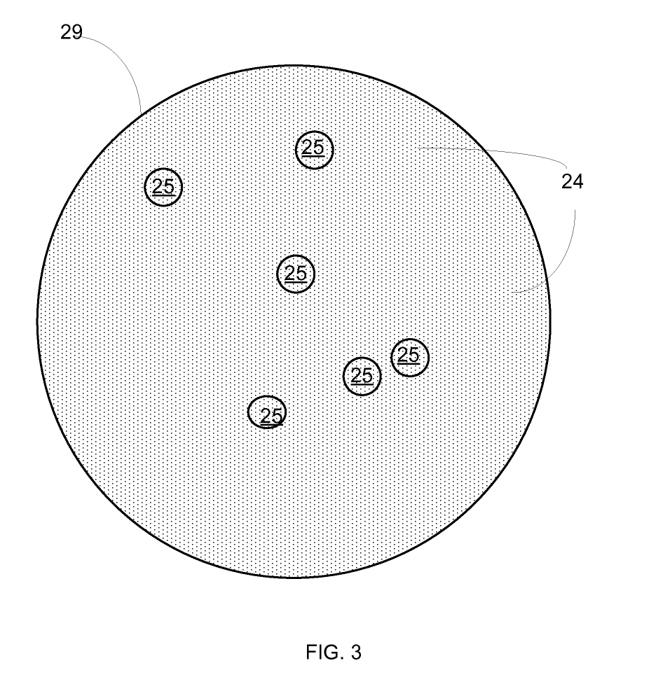

FIG. 1 illustrates a system 100 and a cross section of a wafer in which TSV holes 22 are formed according to an embodiment of the invention. FIG. 2 illustrates a system 100 and a cross section of wafer in which TSVs 24 are loaded. FIG. 3 illustrates a wafer map 29 of wafer 20 which includes TSVs 24 and regions 25 that include extreme TSVs—deepest or shallowest TSVs (TSVs in which the thickness of material between the bottom of the TSV and the backside surface of the substrate is minimal or maximal) according to an embodiment of the invention.

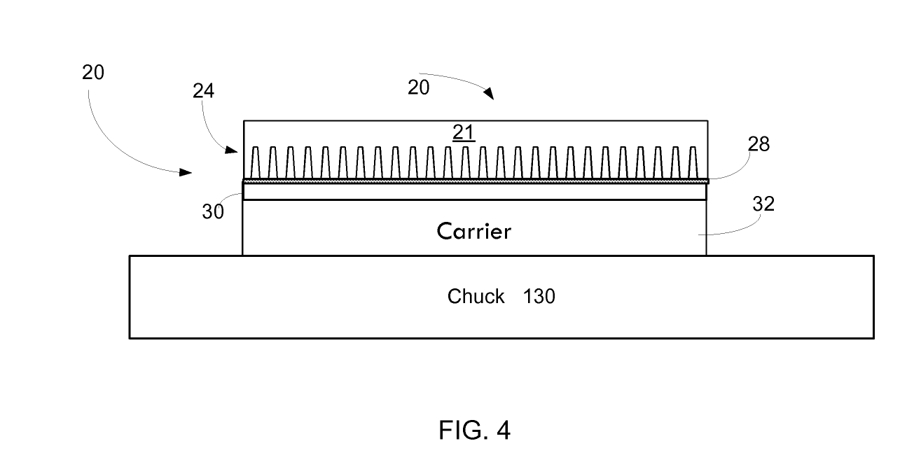

FIG. 4 illustrates a chuck 130 and a cross section of wafer 20 that include a top layer 28, a Silicon bulk 21, (filled) TSVs 24, an adhesive layer 30 and a carrier layer 32 according to an embodiment of the invention. For simplicity of explanation FIGS. 4-14 illustrated filled via holes (filled vias) as objects that have a white filling surrounded by a black line.

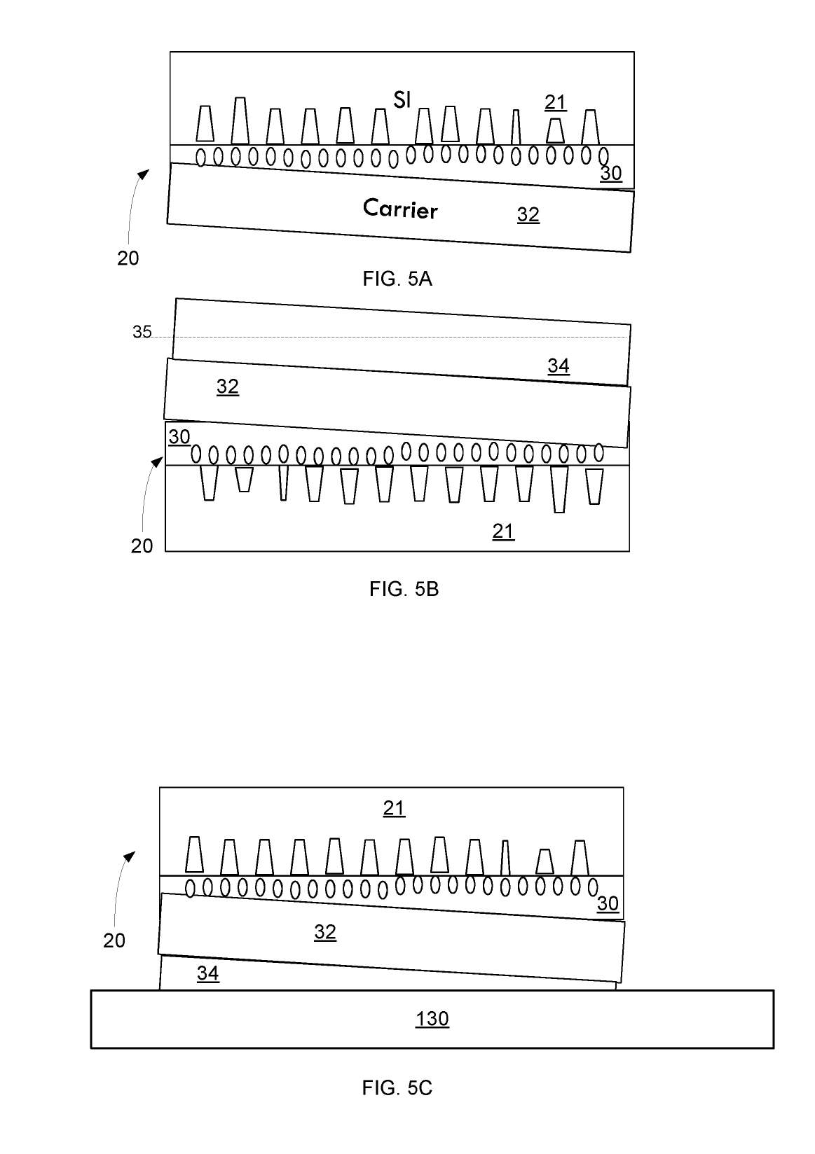

FIG. 5A illustrates a cross section of a wafer 20 before attaching the carrier 32 to an alignment tape, according to an embodiment of the invention.

FIG. 5B illustrates a cross section of a wafer 20 after attaching the wafer to an alignment tape 34, according to an embodiment of the invention.

FIG. 5C illustrates a cross section of a wafer 20 after cutting the alignment tape (along imaginary horizontal line 35) to provide an aligned wafer 20.

Navigation and Measurement

There is provided a method that performs series of various measurements and starting far before the wafer will be sent for thinning process. TSV holes may be made before, after or in between top metal layers will be developed and the measurements will be done regardless the exact timing of TSV manufacturing. Referring to FIG. 1—a bare silicon wafer (20) is processed to introduce the TSV holes 22 on the top side of the wafer. After the TSV holes manufacturing is completed—the TSV holes 22 may be measured—to provide information about (for example) at least one out of the following TSV parameters (dimensions)—an existence or absence of TSV hole, location of TSV holes, diameter of TSV holes, shape of TSV holes, TSV orientation (the orientation is indicative of whether the TSV are vertical or oriented in another angle), depth (12) of TSV holes, distance (13) of TSV holes from a bottom surface 23 of the Silicon wafer. Wafer thickness (11) and Total Thickness Variation (TTV—the variance of the Wafer Thickness across the wafer diameter) is also need to be measured at this stage.

The feedback of measurements results can provide an indication whether to proceed with the manufacturing (thinning process) of the wafer or not. Additionally or alternatively, the information achieved at this stage of TSV′ and Wafer′ measurements will be feed forward to TSV manufacturing equipment and will be used to amend it appropriated recipes in order to improve the process and avoid manufacturing malfunctions detected as result of measurement stage.

The measurements are done by a measurement system 100 that is illustrated as having a processor 120 and a portion 110 that includes (as illustrated in FIG. 2) an illumination module 113 and a detection module 112. The measurements involve illuminating the wafer with electromagnetic radiation (illustrated by dashed line 111). It is noted that the angle or illumination and/or collection may differ from ninety degrees and that the measurements may include dark field measurements, bright field measurements and the like. As indicated above these measurements may be executed by SRM but this is not necessarily so.

FIG. 2 illustrates a measurement of a wafer in which the TSV holes were coated and filled—TSVs 24. The TSV holes may be coated for example with TaN or TiN and then filled with copper (Cu) or Tungsten (W). At this stage the wafer may be inspected (for example by using a 2-D inspection system) to acquire accurate map of the TSVs on the wafer. Additionally or alternatively, the map can be acquired by the measurements (illustrated in FIG. 1) of the wafer in which the TSV were manufactured but not filled yet. Additional TSV parameters (dimensions) can be provided including TSV hole filling parameters—whether a TSV hole was properly filled, whether there are bubbles or any other filling related defects. As indicated above—the generation of the map can be preceded by various measurements (such as mentioned above—for example wafer thickness and TTV). The feedback of measurements results can provide an indication whether to proceed with the manufacturing (thinning process) of the wafer or not. Additionally or alternatively, the information achieved at this stage of TSV′ and Wafer′ measurements will be feed forward to TSV manufacturing equipment and will be used to amend it appropriated recipes in order to improve the process and avoid manufacturing malfunctions detected as result of measurement stage.

The TSV map may include the location of all TSV on the wafer. According to an embodiment of the invention the TSV map may identify regions (such as regions 25 of FIG. 3) that include the deepest TSVs or the shallowest TSVs. In order not to expose deepest TSVs before the rest of TSVs on the wafer their depth during various phases of a grinding process may be monitored.

After a completion of top metal layers manufacturing (denoted 28 in FIG. 4) the wafer is connected to an adhesive layer (denoted 30 in FIG. 4) and carrier 32 and placed on a chuck (denoted 130 in FIG. 4). The carrier may be made of high quality glass and have a thickness of about 600 um. The adhesive thickness is in the range of 50 um.

Although FIG. 4 illustrates a perfect alignment between the carrier 32, the adhesive 30, the Silicon bulk 21 and an imaginary horizon. In many cases these elements are not aligned (parallel) to each other—as illustrated in FIG. 5A. In order to provide an alignment between the chuck and the Silicon bulk 21—an alignment tape 34 is connected to the carrier 32 and it is grinded in a manner (see horizontal dashed line 35 extending within the oriented alignment tape 34) to provide alignment. Once the alignment tape is grinded the wafer (now attached to the grinded alignment tape 34) is flipped to place the grinded alignment tape 34 on the chuck 130 while the back end surface of the Silicon bulk is not the upmost part of the wafer.

The wafer can be examined for alignment—and if a satisfactory alignment is not provided—the alignment tape can be either grinded again or replaced by another alignment tape that is then grinded and the process is then repeated. If a satisfactory alignment is provided the adhesive can be cured.

Each wafer may contain large number of TSVs (˜5×10⁶)—the TSV map may include any of the mentioned above TSV parameters such as depth, shape, location and like. The data may provide full statistics of the TSVs depths and to indicate for the regions (denoted 25 in FIG. 3) where the deepest TSV or shallowest TSV are placed and their coordinates.

According to an embodiment of the invention the grinding process occurs after measuring the depths of TSVs and searching for the deepest TSVs. Additionally or alternatively, such measurements can be conducted after the grinding process started. The method may proceed by measuring a full thickness backside wafer—using infrared (IR) or near infrared (NIR) microscopy. After wafer alignment or alternatively if no alignment required—without need for alignment, IR or NIR radiation may scan the regions that include the deepest TSVs (TSVs where the thickness of the material between the bottom of the TSV and the backside surface of the substrate is minimal—marked as 13 in FIG. 1) to measure the thickness of remaining Silicon (distance from the bottom wafer surface to the deepest TSV—marked as 13 at FIG. 1).

Based on this data across the wafer, the coarse grinding phase can be performed with fast vertical feed rate without concern on getting too close to the TSVs ends or even impinge them. Measurement of the remaining silicon thickness above the bottom end of the TSVs will be provided to a thinning devise as a feedback for performing efficient thinning process such as coarse grinding that will follow the specific condition of the wafer thickness and TTV, distribution of TSVs depth across the wafer and to compensate for any change that is experienced in the grinding system (e.g. grinding pads ware-out, temperature fluctuations, excessive accumulated material etc.). In addition or alternatively, measurement of the remaining silicon thickness may be feed forward to TSV manufacturing equipment and will be used to amend it appropriated recipes in order to improve the process and avoid manufacturing malfunctions detected as a result of such measurement.

The grinding time duration for each grinding subset (during coarse and fine grinding procedures) is updated in real time based on the calculation result of the change that is found for the GR_{Cg}. A processor (120) can include a feed forward module that may update two major parameters in real time and based on in-situ near IR (or NIR) sensor imaging and thickness measurement during the grinding process, the time duration and the vertical feed rate of the grinding wheel.

When the coarse phase of the coarse grinding reached to about 20 um above the deepest TSV reached—the grinding device may enter a fine grinding phase in which a finer grinding wheel is used.

The measurement system can perform, before starting the fine grinding process, during the fine grinding process or after the fine grinding process ends, measurement with very high accuracy of the remaining silicon thickness above the deepest TSVs. The measurements can be fed to a feed forward module that may calculate the required time to further grind the wafer and updating both parameters the grinding time and the vertical feed rate which control the material grinding rate.

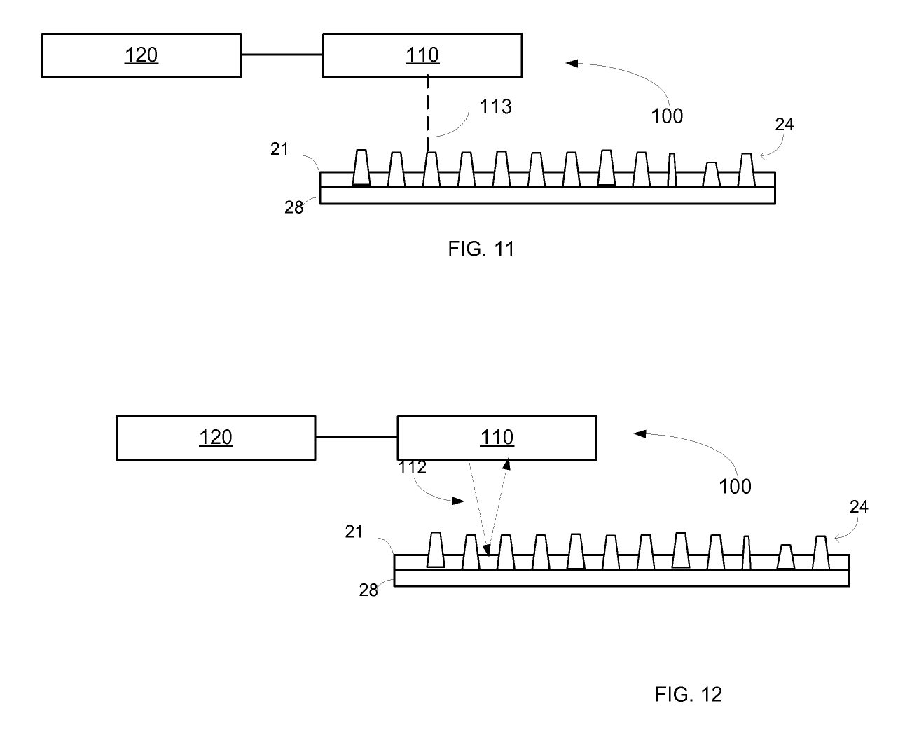

The grinding process may be followed by an etching process. FIGS. 11 and 12 illustrate inspection systems 100 that inspect a post etched wafer in order to provide TSV measurements. The TSVs are exposed—and their back ends extend above the reminded of the Silicon bulk 21. Portion 110 of the system 100 of FIG. 11 may include a CCS module while the portion 110 of system 100 of FIG. 12 may include a CTS module.

When the wafer is first loaded into the system IR (or NIR) microscopy is used to the image the TSVs bottom ends through the Silicon bulk of wafer backside. This is done in the order to locate the region of interest (ROI). Excellent IR images can be constructed through more than 800 um thick Silicon. In general, increase in the wafer thickness and in the silicon doping reduces the image quality due to the absorption of IR light by the Silicon. NIR radiation may be collected, for example, by InGaAs-based detectors.

Feed Forward and Feed Back

This process can be used also for what is known as feed back process. Measurement data of Wafer Thickness, TTV and TSV wafer map that is received before starting the grinding of a wafer can be used to update process, calculate time and the grinding profile to be applied to the wafer. This feed-back technique is useful to compensate for any variations and differences in the incoming wafers. The feed back can also be used to correct, update or instruct the grinding device to change its grinding parameters, before, during or after the thinning process.

The feedback and/or feed forward module will use also feed forward technique. This process will not compensate of changes on the incoming material but for changing in grinding time and grinding rate (via vertical grinding feed rate). The grinding profile which is composed of grinding time and vertical feed rate parameters are updated in real time. This profile is recorded and used for the next wafer. Feedback usually used for discrimination of failed wafers, which do not comply with the spec requirements.

There were provided methods and device for processing the backside of the wafer and thinning under real time control procedure which allows reaching to a remaining silicon thickness target of 1-2 um with efficient time processing and minimal damage. This will enable the users save the manufacturing costs by improving the yield and to increase the throughput.

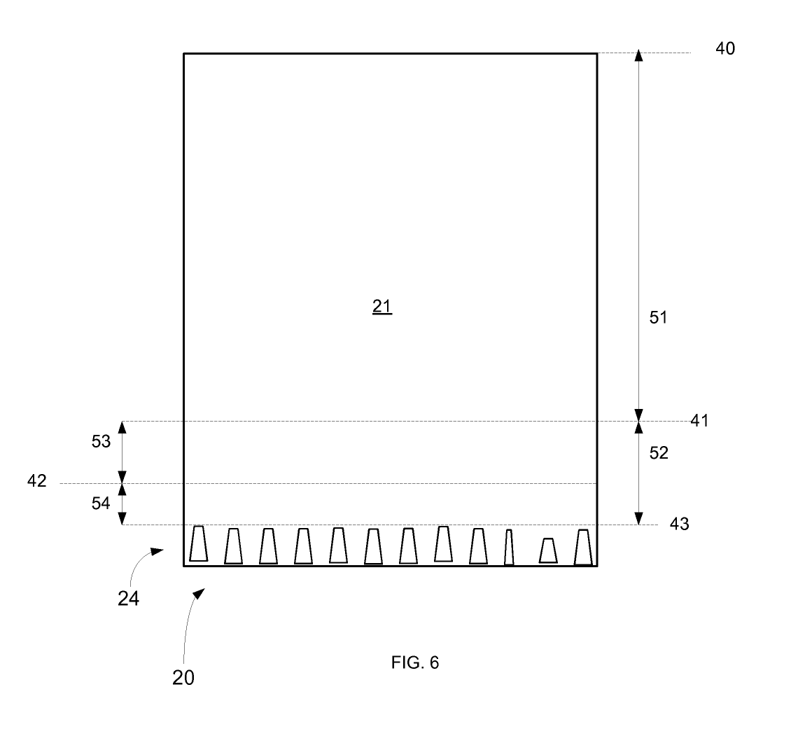

FIG. 6 illustrates a cross section of a wafer 20, and various dimensions that are associated with a fine phase and a coarse phase of a grinding process according to an embodiment of the invention.

The coarse grinding process is expected to start grinding the Silicon bulk from an initial imaginary horizontal line 40 and remove the Silicon till reaching an intermediate imaginary horizontal line 41. This involves removing a first amount of Silicon of first thickness 51. At the end of the gross grinding phase the TSVs are expected to be at an intermediate distance 52 from the back end surface of the Silicon bulk (now located at the intermediate imaginary horizontal line 41). The fine grinding process is expected to start grinding the Silicon bulk from the intermediate imaginary horizontal line 41 and remove the Silicon till reaching a final imaginary horizontal line 42. This involves removing a second amount of Silicon of second thickness 53. At the end of the fine grinding phase the TSVs are expected to be at a final distance 54 from the back end surface of the Silicon bulk (now located at the final imaginary horizontal line 43).

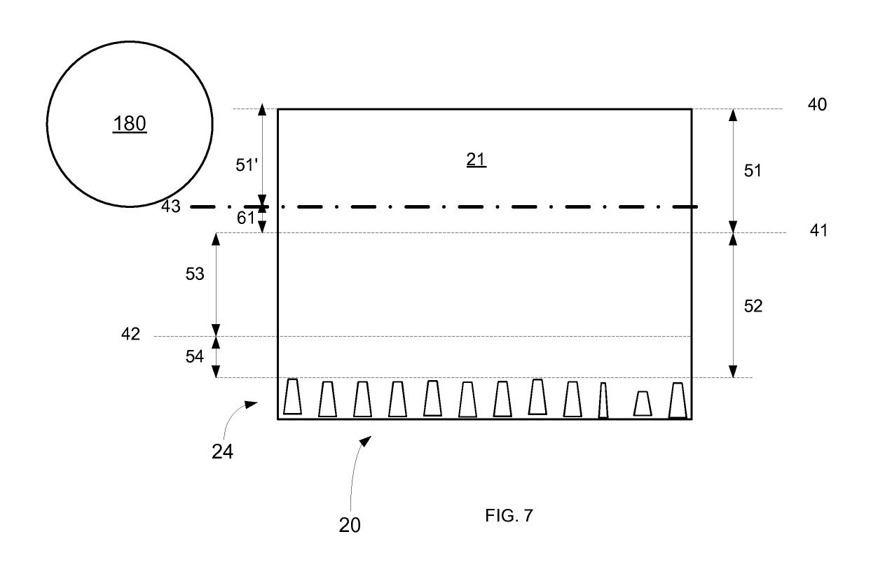

FIG. 7 illustrates a cross section of a wafer 20 after a completion of a coarse phase of a grinding process, and various dimensions that are associated with a fine phase and the coarse phase of the grinding process according to an embodiment of the invention. FIG. 7 illustrates that there is a gap 61 between (a) the expected state of the wafer at the end of the coarse grinding phase and (b) the actual state of the wafer at the end of the coarse grinding phase. Instead of grinding the Silicon bulk till reaching the intermediate imaginary line 41—the coarse grinding phase ended when reaching an intermediate actual line 43 that is higher than the intermediate imaginary line 41—there is a gap 61 between lines 41 and 43 and only a Silicon layer of thickness 51′ was removed. FIG. 7 also illustrates grinding device 180 that performed the grinding process.

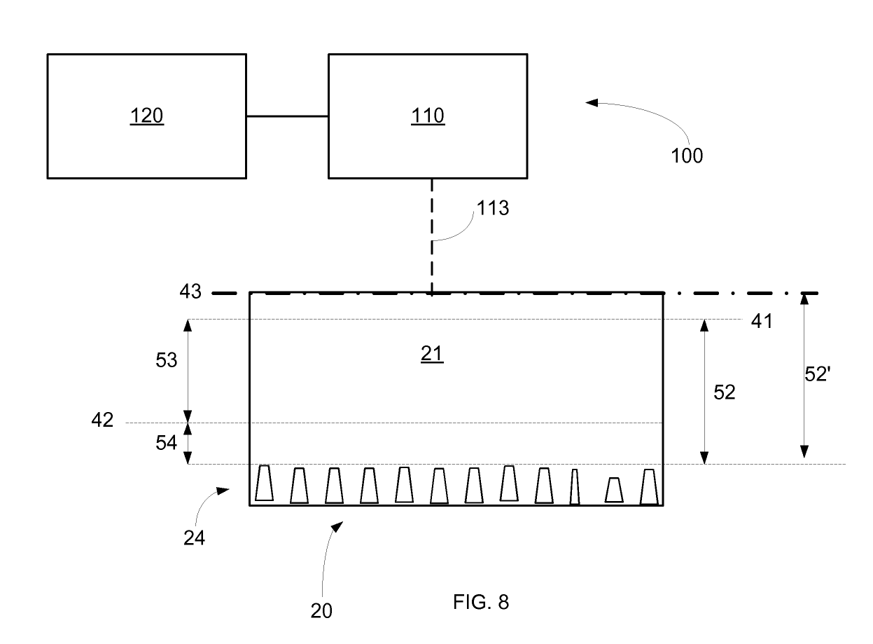

FIG. 8 illustrates system 100 that measures depths of TSVs of a wafer that was coarsely grinded according to an embodiment of the invention. It can calculate the gap 61 and may respond to the gap—for example by informing the grinding device, by instructing the grinding device to change one or more of its grinding parameters and the like. Although FIGS. 7 and 8 illustrates a coarse grinding process that grinded less Silicon than expected—the coarse grinding process may also grind more Silicon than expected—and system 100 may respond accordingly.

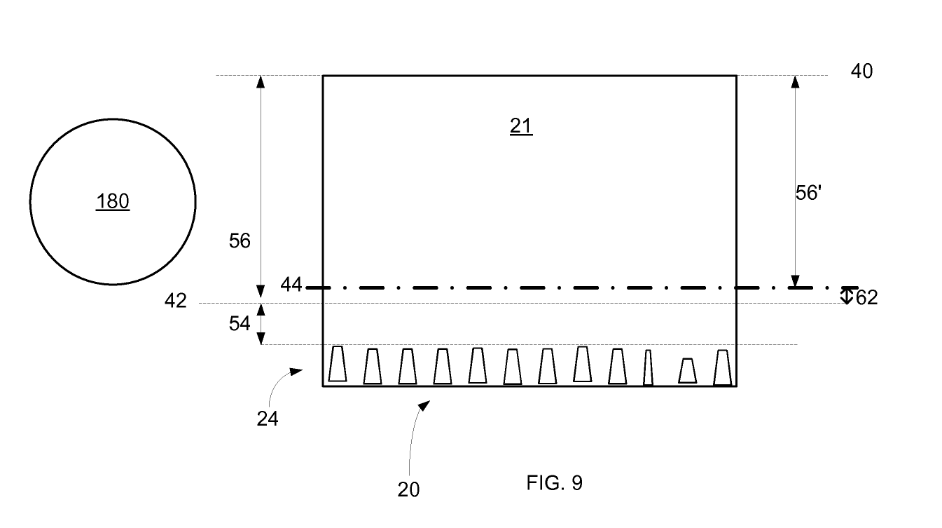

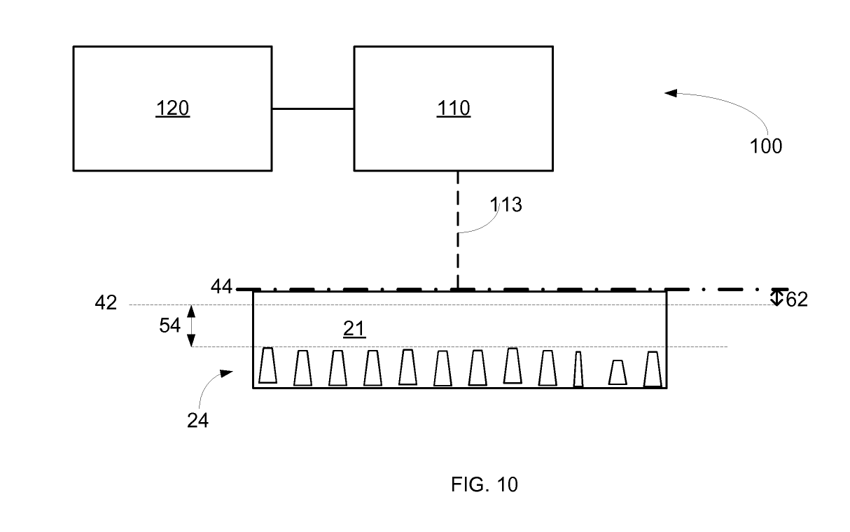

FIG. 9 illustrates a cross section of a wafer 20 after a completion of a fine phase of a grinding process, and various dimensions that are associated with the fine phase of the grinding process according to an embodiment of the invention. FIG. 10 illustrates a system 100 that measures depths of TSVs of a wafer that was coarsely and finely grinded according to an embodiment of the invention.

FIG. 9 illustrates that there is a gap 62 between (a) the expected state of the wafer at the end of the fine grinding phase and (b) the actual state of the wafer at the end of the fine grinding phase. Instead of grinding the Silicon bulk till reaching the final imaginary line 42—the fine grinding phase ended when reaching a final actual line 44 that is higher than the final imaginary line 42—there is a gap 62 between lines 42 and 44 and only a Silicon layer of thickness 56′ was removed during the fine and coarse grinding phases. FIG. 9 also illustrates grinding device 180 that performed the grinding process.

FIG. 10 illustrates system 100 that measures depths of TSVs of a wafer that was coarsely grinded according to an embodiment of the invention. It can calculate the gap 62 and may respond to the gap—for example by informing the grinding device, by instructing the grinding device to change one or more of its grinding parameters and the like. Although FIGS. 9 and 10 illustrates a coarse grinding process that grinded less Silicon than expected—the coarse grinding process may also grind more Silicon than expected—and system 100 may respond accordingly.

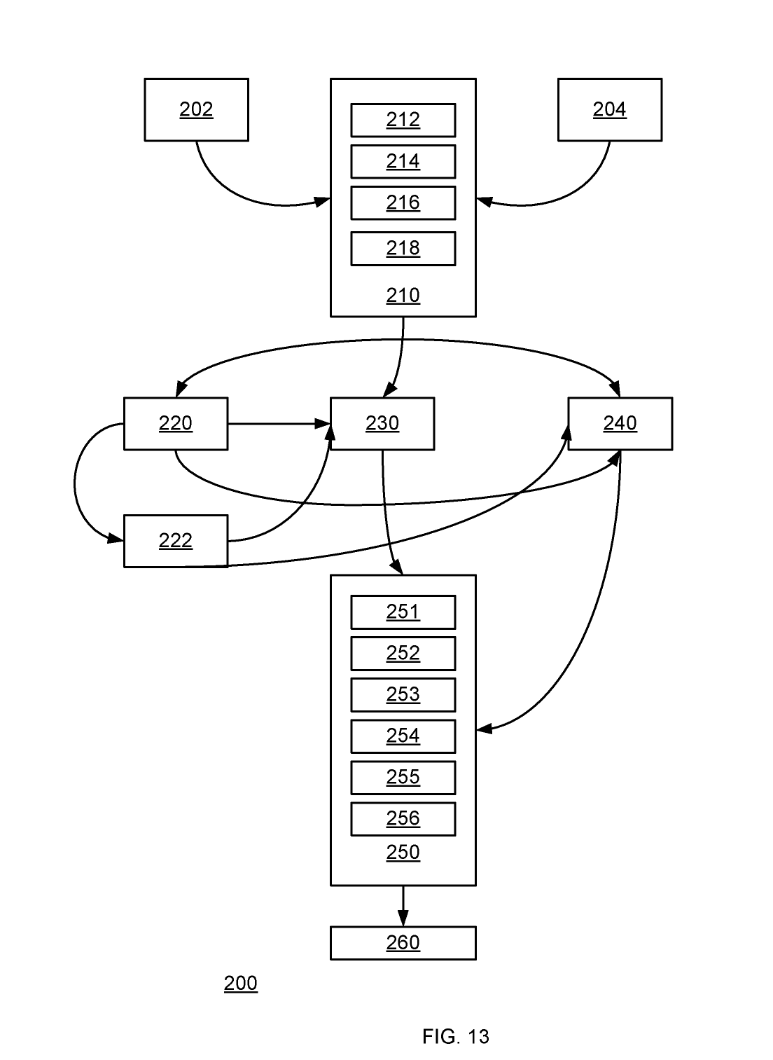

FIG. 13 illustrates method 200 according to an embodiment of the invention.

Method 200 may be executed by system 100 of any of the previous figures.

Method 200 may start by stages 202 and/or 204.

Stage 202 may include measuring dimensions—parameters (as specified, for example in par. [0055] and [0058]) of multiple through silicon vias that are deposited within a wafer to provide first through Silicon via (TSV) measurement results. The measuring may include illuminating the TSVs with electromagnetic radiation.

Stage 204 may include measuring Silicon wafer thickness at multiple locations to provide first wafer thickness and total thickness variation results (see, for example FIGS. 1-2).

Stage 202 and 204 may be followed by stage 210 of responding to at least the first TSV measurement results before manufacturing wafer top metal layers.

The responding may include providing information related to at least one out of (a) the first substrate thickness results and (b) the first via measurement results (such as first TSV measurement results), to at least one out of (i) a thinning device arranged to thin the substrate and (ii) a manufacturing device that differs from the thinning device and is arranged to participate in a manufacturing of the substrate.

Stage 210 may include stage 212 of determining to stop a manufacturing of the wafer.

Stage 210 may include stage 214 of sending the first TSV measurement results and the first wafer thickness and TTV results to a grinding device.

Stage 210 may include stage 216 of calculating initial thickness of material between the bottom of vias and the backside surface of the substrate. This initial value is calculated before a start of a grinding process of the Silicone bulk.

Stage 210 may include stage 218 of sending information relating to the initial thickness of material between vias and the backside surface of the substrate s to a grinding device. The information relating to the initial thickness of material between vias and the backside surface of the substrate may include information about location of extreme vias and the initial thickness of material between the extreme vias and the backside surface of the substrate (for example—TSV map 29 of FIG. 3).

Stage 210 may be followed by stage 220, 230 and/or stage 240.

Stage 220 may include measuring an alignment of a wafer to provide first alignment results, wherein the measuring of the alignment occurs after the manufacturing of the wafer top layer elements and before initializing a grinding process of the Silicon bulk. See, for example, FIG. 5.

Stage 220 may be followed by stage 222 of determining to remove an alignment tape from the wafer and to attach a new alignment tape to the wafer in response to the alignment results. Stages 220 and 222 may be followed by stage 230 or 240.

Stage 230 may include measuring before initializing the grinding process the depths of the TSV—including the depths of the deepest TSVs. This measuring may include finding the locations of the deepest TSVs based on the TSV map. Stage 230 may be followed by stage 250.

Stage 240 may include measuring, after initializing a grinding process of the Silicone bulk and before completing the grinding process, intermediate depths of TSVs of the multiple TSVs. This may be executed when a coarse grinding phase ends (see, for example FIGS. 7 and 8), during the coarse grinding phase and even during the fine grinding phase.

Stage 240 may be followed by stage 250 of providing information related to at least one of (a) the first substrate thickness results and (b) the first via measurement results to at least one out of (i) a thinning device arranged to thin the substrate and (ii) a manufacturing device that differ from the thinning device and is arranged to participate in a manufacturing of the substrate.

Stage 250 may include any one of stages 251-256 and may be followed by stage 260

Stage 251 may include sending information relating to the intermediate thickness of material between vias and the backside surface of the substrate of the TSVs to a grinding device that performs the grinding process.

Stage 252 may include inferring or detecting estimations made by the grinding device about the thickness of material between vias and the backside surface of the substrate of the TSVs. This may include monitoring distinctive points in the grinding process (for example—start or end point of grinding phases) that are associated with known Silicon removal amounts (or known distances to TSVs), monitoring the grinding parameters (such as monitoring the speed of grinding and the duration of grinding) or receiving from the grinding device the estimations.

Stage 253 may include calculating gaps between the intermediate thickness of material between vias and the backside surface of the substrate of the TSVs and estimations made by the grinding device about the thickness of material between vias and the backside surface of the substrate of the TSVs.

Stage 254 of responding to the gaps.

The responding may include providing information related to at least one out of (a) the first substrate thickness results and (b) the first via measurement results (such as first TSV measurement results), to at least one out of (i) a thinning device arranged to thin the substrate and (ii) a manufacturing device that differs from the thinning device and is arranged to participate in a manufacturing of the substrate.

Stage 255 of alerting the grinding device about the gaps.

Stage 256 of instructing the grinding device to alter a grinding parameter or to stop the grinding process.

Stages 255 and 256 may be included in stage 254.

Stage 250 may be followed by stage 260 of performing post etch measurement of the TSVs, wherein the post etch measurements are executed after an exposure of the TSVs by an etching process that follows the grinding process. See, for example, FIG. 11).

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

However, other modifications, variations and alternatives are also possible. The specifications and drawings are, accordingly, to be regarded in an illustrative rather than in a restrictive sense.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

1. A system for controlling a manufacturing process of a substrate, the system comprises:
an illumination module that is arranged to illuminate multiple regions of a substrate with electromagnetic radiation;
a detection module that is arranged to detect electromagnetic signals resulting from the illumination of the multiple regions; and
a processor that is arranged to:
determine via information related to multiple vias that are deposited within the substrate to provide first via measurement results;
determine substrate thickness at multiple locations to provide first substrate thickness results; and
provide information related to at least one out of (a) the first substrate thickness results and (b) the first via measurement results, to at least one out of (i) a thinning device arranged to thin the substrate and (ii) a manufacturing device that differs from the thinning device and is arranged to participate in a manufacturing of the substrate.

2. The system according to claim 1 wherein the processor is arranged to determine to stop at least one out of (a) a manufacturing of the substrate and (b) a thinning of the substrate.

3. The system according to claim 1 wherein via information related to a via out of the multiple vias reflects at least one out of an existence of a via hole, an absence of the via hole, a location of the vias hole, a diameter of the via hole, a shape of the via hole, an orientation of the via hole, a depth of the via hole, a filling status of the via hole and a thickness of material between vias and the backside surface of the substrate.

4. The system according to claim 1 wherein the processor is arranged to send the first via measurement results and the first substrate thickness results to a grinding device.

5. The system according to claim 1, wherein the processor is arranged to determine an alignment of a substrate to provide first alignment results, wherein a measurement of the alignment occurs after the manufacturing of the substrate top metal layers and before initializing a grinding process of the substrate.

6. The system according to claim 4 wherein the processor is arranged to determine to remove an alignment tape from the substrate and to attach a new alignment tape to the substrate in response to the alignment results.

7. The system according to claim 1 wherein the processor is arranged to:
calculate initial thickness of material between vias and the backside surface of the substrate at multiple locations occurring at at least one out of the following time frames (a) before initializing a grinding process of the substrate, (b) after an initialization of a grinding process of the substrate and (c) before a completion of the grinding process and
participate in a sending of information relating to the initial thickness to at least one out of the following (a) a grinding device and (b) a manufacturing of the substrate device.

8. The system according to claim 6 wherein the information relating to the initial thickness of material between vias and the backside surface of the substrate at multiple location comprises information about location of extreme vias and thickness of material between extreme vias and the backside surface of the substrate.

9. The system according to claim 6 wherein the processor is arranged to calculate gaps between the initial thickness of material between vias and the backside surface of the substrate and estimations made by the grinding device about the thickness of material between vias and the backside surface of the substrate, and responding to the gaps.

10. The system according to claim 9 wherein the processor is arranged to participate in an alerting of the grinding device about the gaps.

11. The system according to claim 9 wherein the processor is arranged to participate in an instructing of the grinding device to alter a grinding parameter.

12. The system according to claim 9 wherein the processor is arranged to determine the estimations made by the grinding device in response to a detection of grinding device action related to the grinding process.

13. The system according to claim 12 wherein the grinding device actions related to the grinding process comprise an end of a rough grinding phase of the grinding process and an end of a fine grinding phase of the grinding process.

14. The system according to claim 1 wherein the illumination module is arranged to illuminate a plurality of regions of a post etched substrate with electromagnetic radiation; wherein the illumination occurs after an exposure of the vias by an etching process that follows the grinding process; wherein the detection module is arranged to detect electromagnetic signals resulting from the illumination of the plurality of regions; and wherein the processor is arranged to determine vias dimensions of the exposed vias.

15. A method for controlling a manufacturing process of a substrate, the method comprising:
determining via information related to multiple vias that are deposited within the substrate to provide first via measurement results;
wherein the determining comprises illuminating the vias with electromagnetic radiation;
measuring substrate thickness at multiple locations to provide first substrate thickness results; and
providing information related to at least one out of (a) the first substrate thickness results and (b) the first via measurement results to at least one out of (i) a thinning device arranged to thin the substrate and (ii) a manufacturing device that differs from the thinning device and is arranged to participate in a manufacturing of the substrate.

16. The method according to claim 15 wherein via information related to a via out of the multiple vias reflects at least one out of an existence of a via hole, an absence of the via hole, a location of the vias hole, a diameter of the via hole, a shape of the via hole, an orientation of the via hole, a depth of the via hole, a filling status of the via hole and a thickness of material between vias and the backside surface of the substrate.

17. The method according to claim 15 that is executed by a system that comprises an illumination module that is arranged to illuminate multiple regions of the substrate with electromagnetic radiation; a detection module that is arranged to detect electromagnetic signals resulting from the illumination of the multiple regions; and a processor that is arranged to: determine dimensions of the multiple vias to provide the first via measurement results; determine the substrate thickness at multiple locations to provide the first substrate thickness results; and participate in a response to at least the first via measurement results.

18. The method according to claim 15 wherein the responding comprises determining to stop at least one process out of (a) a manufacturing of the substrate and (b) thinning of the substrate.

19. The method according to claim 15 wherein the responding comprises sending the first via measurement results and the first substrate thickness results to a grinding device.

20. The method according to claim 15, comprising measuring an alignment of a substrate to provide first alignment results, wherein the measuring of the alignment occurs after the manufacturing of the substrate top metal layers and before initializing a grinding process of the substrate.

21. The method according to claim 20 comprising determining to remove an alignment tape from the substrate and to attach a new alignment tape to the substrate in response to the alignment results.

22. The method according to claim 15 wherein the responding comprises:
calculating initial thickness of material between vias and the backside surface of the substrate at multiple locations occurring at at least one out of the following time frames (a) before initializing a grinding process of the substrate, (b) after an initialization of a grinding process of the substrate and (c) before a completion of the grinding process and
participating in a sending of information relating to the initial thickness to at least one out of the following (a) a grinding device and (b) a manufacturing of the substrate device.

23. The method according to claim 22 wherein the information relating to the initial thickness of material between vias and the backside surface of the substrate comprises information about location of extreme vias and thickness of material between the extreme vias and the backside surface of the substrate.

24. The method according to claim 22 comprising calculating gaps between the initial thickness of material between vias and the backside surface of the substrate and estimations made by the grinding device about the thickness of material between vias and the backside surface of the substrate, and responding to the gaps.

25. The method according to claim 23 wherein the responding to the gaps comprises alerting the grinding device about the gaps.

26. The method according to claim 23 wherein the responding to the gaps comprises instructing the grinding device to alter a grinding parameter.

27. The method according to claim 23 comprising determining the estimations made by the grinding device in response to a detection of grinding device action related to the grinding process.

28. The method according to claim 23 wherein the grinding device actions related to the grinding process comprise an end of a rough grinding phase of the grinding process and an end of a fine grinding phase of the grinding process.

29. The method according to claim 15 comprising performing post etch measurement of the vias, wherein the post etch measurements are executed after an exposure of the vias by an etching process that follows the grinding process.
